(19) United States
(12) Patent Application Publication
(10) Pub. No.: US 2012/0268119 A1
(43) Pub. Date: Oct. 25, 2012

(54) MAGNETIC FIELD ADJUSTMENT METHOD FOR MRI DEVICE

(75) Inventors: Mitsushi Abe, Hitachinaka (JP); Ryuya Ando, Hitachi (JP)

(73) Assignee: HITACHI, LTD., Tokyo (JP)

(21) Appl. No.: 13/511,786

(22) PCT Filed: Nov. 24, 2010
(86) PCT No.: PCT/JP2010/070881

§ 371 Date: May 24, 2012

(30) Foreign Application Priority Data
Nov. 24, 2009 (JP) 2009-265849

(51) Int. Cl. G01R 33/44

(52) U.S. Cl. 324/307

(57) ABSTRACT

An eigen-mode to be corrected is selected in accordance with an attainable magnetic field accuracy (homogeneity) and appropriateness of arranged volume of the iron pieces. Because the adjustment can be made with the attainable magnetic field accuracy (homogeneity) being grasped, an erroneous adjustment can be grasped, and the adjustment is automatically done during repeated adjustment. When the magnetic field adjustment is carried out with support by the method of the present invention according to the first and second embodiments or an apparatus including this method therein, the magnetic field adjustment can be surely completed. As a result, the apparatus with a high accuracy can be provided. In addition, there is an advantageous effect of earlier detection of a poor magnet by checking the attainable homogeneity. They are applicable to magnet devices for the horizontal magnetic field type, being an open type MRI, and vertical magnetic field type MRI.

### TECHNICAL FIELD

The present invention relates to a superconducting magnet apparatus and a nuclear magnetic resonance tomographic apparatus (Magnetic Resonance Imaging).

### BACKGROUND ART

In diagnosis using a nuclear magnetic resonance, a required accuracy in a magnetic intensity of the magnet system is such that variation of one millionth in magnetic intensity is considered to be a problem because a magnetic intensity corresponds to a diagnosis place. There are three types of magnetic fields in MRI devices. That is:

(1) A magnetic field that is a constant in time base and uniform in space, and has an intensity of generally more than 0.1 to several teslas and a variation range of about several ppm within a space for imaging (a space of a sphere or an ellipsoid with a diameter of 30 to 40 cm);
(2) A magnetic field varying with a time constant of about one second or shorter and inclined in a space; and
(3) An electromagnetic wave caused by a high frequency wave having a frequency (several MHz or higher) corresponding to the nuclear magnetic resonance.

Out of them, the magnetic field of (1) is required to be constant in time base and spatially have homogeneity in the magnetic intensity with an extremely high accuracy in the region where a tomographic imaging of a human body is done. “High accuracy” means that an accuracy with an order of one millionth, such as ±1.5 ppm, in an imaging space FOV (Field of View) with a diameter of, for example, 40 cm. A magnetic field distribution of which homogeneity is required to be extremely high, requires adjustment for a magnetic field after production and excitation of a magnet. Generally, an error in magnetic field in production is 1000 times or more greater than the permissible error margin of the magnetic field demanded for a uniform magnetic field. Magnetic field adjustment (shimming) required when the apparatus is installed after production requires a magnetic field adjustment apparatus and a method with an extremely high accuracy because an error in magnetic field is reduced from hundreds ppm to several ppm.

There is a conventional method of shimming using a linear programming. For example, there is the method described in JP 2001-87245 or JP 2003-167941 and applied to actual apparatuses for adjustment. However, the linear programming has the following problems.

(1) The liner programming requires a long time period for calculation to conduct accurate calculations of the magnetic field.
(2) The linear programming requires such an accuracy that a magnetic field with a high accuracy is controlled in accordance with setting and variation of each iron piece and current.
(3) When an erroneous shimming operation is conducted, it is difficult to specify the place where the erroneous shimming operation is done, so that restoration requires a lot of work.

In addition, a problem occurs due to adjusting the magnetic field distribution with spherical harmonic functions as shown in FIG. 2. FIG. 2 is a chart showing an example of a conventional magnetic field adjustment method using the spherical harmonic functions (JP 2001-87245).

The spherical harmonic functions are orthogonal on a spherical surface to form a base, but when a magnetic field with a spherical function distribution having a high accuracy is tried to generate, a fine adjustment for a magnetic adjustment mechanism is required because there is a mutual interference in the magnetic field adjustment mechanism and on a magnetic field evaluation surface of an aspheric surface. For example, a homogeneous magnetic field distribution is a distribution having the lowest-numbered spherical harmonic functions. However, it is impossible to actually generate this distribution accurately unless using a magnetic adjustment mechanism which perfectly encloses a magnetic adjustment region. Accordingly, the MRI of the prior art has no such a magnetic adjustment mechanism.

### PRIOR ART TECHNICAL DOCUMENTS

### Patent Documents

Patent Document 1: JP 2001-87245
Patent Document 2: JP 2003-167941
Patent Document 3: JP 2001-327478

### Non-Patent Document

Non-Patent Document 1: M. ABE, T. NAKAYAMA, S. OKAMURA, K. MATSUOKA, “A new technique to optimize coil winding path for the arbitrarily distributed magnetic field and application to a helical confinement system”, Phys. Plasmas. Vol. 10 No. 4 (2003)1022.

### DISCLOSURE OF THE INVENTION

### Summary of Invention

### Problem to be Solved by Invention

An object of the present invention is to provide a method and an apparatus in which the above-mentioned problem can be solved and adjustment can be surely completed with confirming a progress status of the adjustment and a prospect as to which degree the final erroneous magnetic field can be reduced to. Another object of the present invention is to provide a method including a function capable of easily, automatically, performing correction to quickly complete the adjustment even if the operation is erroneously done and to provide an apparatus with the method, wherein the apparatus displays an indication of the magnetic field adjustment method.

### Measures for Solving the Problem

As a method of obtaining a current distribution for a target magnetic field on a given surface such as a curved surface or a flat surface, there is a method with current potential described in a paper (Non-patent document 1). This calculation method is named DUCAS in the paper. The magnetic field adjustment is performed by applying this DUCAS method, particularly, by applying the idea of a current potential and a singular value decomposition used in the method.

In DUCAS in the non-patent document 1, a magnetic field distribution to be entered as an error magnetic field to be corrected is a difference from a magnetic field distribution calculated using the current potential, etc. which are associated with assumption of the target magnetic field determined in a plasma confinement theory, i.e., values obtained by a numeric value calculation. On the other hand, because the present invention targeted on an actual apparatus, a difference between a target magnetic field and a measured magnetic field is defined as an error magnetic field and a lot of measurement magnetic field at a lot of points are dealt to grasp an error magnetic field distribution.

In addition, in the non-patent document 1, a distribution of a current potential T is obtained, in which case a current density vector j is a vector product of current potential \vec{T} and a normal vector on a surface, and thus a current is obtained from (V\vec{T})×\vec{n}, a contour line of \vec{T} is shown as line currents or in a coil shape. However, in the present invention, it is a magnetic moment distribution or an iron piece density distribution.

### Advantageous Effect of the Present Invention

According to the present invention, an MRI device that generates a magnetic field with a high accuracy can be produced at a low cost. In addition, in place of the MRI, the present invention is applicable to a magnetic field adjustment method for a magnet requiring magnetic field having a high accuracy.

### BRIEF DESCRIPTION OF DRAWINGS

FIG. 1 illustrates a magnetic field adjustment flowchart of a preferred embodiment of the present invention.

FIG. 2 illustrates a conventional shimming flowchart.

FIG. 3 is illustrations of an idea of conversion between current potential and a magnetized iron piece volume for the magnetic field adjustment which is necessary for correcting the magnetic field according to the preferred embodiment of the present invention.

FIG. 4 is a chart of an example of a general system of a calculation system used in an embodiment of the present invention.

FIG. 5 illustrates an arrangement illustration of the magnetic adjustment mechanism for an MRI magnet used for magnetic field adjustment of the embodiment of the present invention.

FIG. 6 illustrates an illustration of a calculation model for applying the present invention to the magnetic field adjustment shown in FIG. 5.

FIG. 7 illustrates charts showing spectrums of magnetic field distribution together with an attainable homogeneity, in which (a) illustrates the spectrum before shimming and (b) illustrates the spectrum after shimming.

FIG. 8 illustrates a display example of iron piece volume arrangement for adjusting a magnetic field correction on a shim-tray together with the current potential contour line according to the present invention.

FIG. 9 illustrates an idea of a magnetic moment calculation and an iron piece volume conversion within a mesh for displaying an iron piece, according to the present invention.

FIG. 10 is a flowchart in a case where the present invention is used in a magnet motive force arrangement designing method.

FIG. 11 is an illustration for illustrating a whole of a horizontal magnetic field type of MRI to which an embodiment of the present invention is applied.

FIG. 12 is an illustration illustrating a relationship between a position of a shim-tray and an imaging region in a cross section view of a magnet device of the horizontal magnetic field type of MRI to which an embodiment of the present invention is applied.

FIG. 13 is a drawing of a calculation system for simulating the shim-tray of the horizontal magnetic field type of MRI. A face for evaluation of a current potential to obtain an iron volume for shimming is arranged in ring shape.

FIG. 14 is a schematic drawing of the shim-tray in which a volume of iron piece for finely adjusting the magnetic field is changed depending on position.

FIG. 15 is an illustration illustrating a calculation result of current potentials on a current potential evaluation surface (on a lower side) in which magnetic moments at regions sectioned with meshes are converted into iron volumes, and an iron piece is arranged at the same location on the shim-tray indicted on the upper side with a value of the calculation result.

FIG. 16 is an illustration illustrating a thinking way of calculating magnetic movements within meshes, in which magnetic moment at a node is surface-integrated at a region corresponding to the mesh of the shim-tray.

FIG. 17 is an illustration illustrating iron piece arrangement within a mesh in which iron piece volumes are arranged within the mesh with a volume of a calculation, but is divided into some previously prepared volumes.

FIG. 18 is a conception drawing in a case where the magnetic moment is substituted for a current loop, in which the magnetic movement is adjusted with an area surrounded by a loop which is a small coil and a current.

### MODE FOR CARRYING OUT THE INVENTION

With reference to drawings will be described embodiments of the present invention.

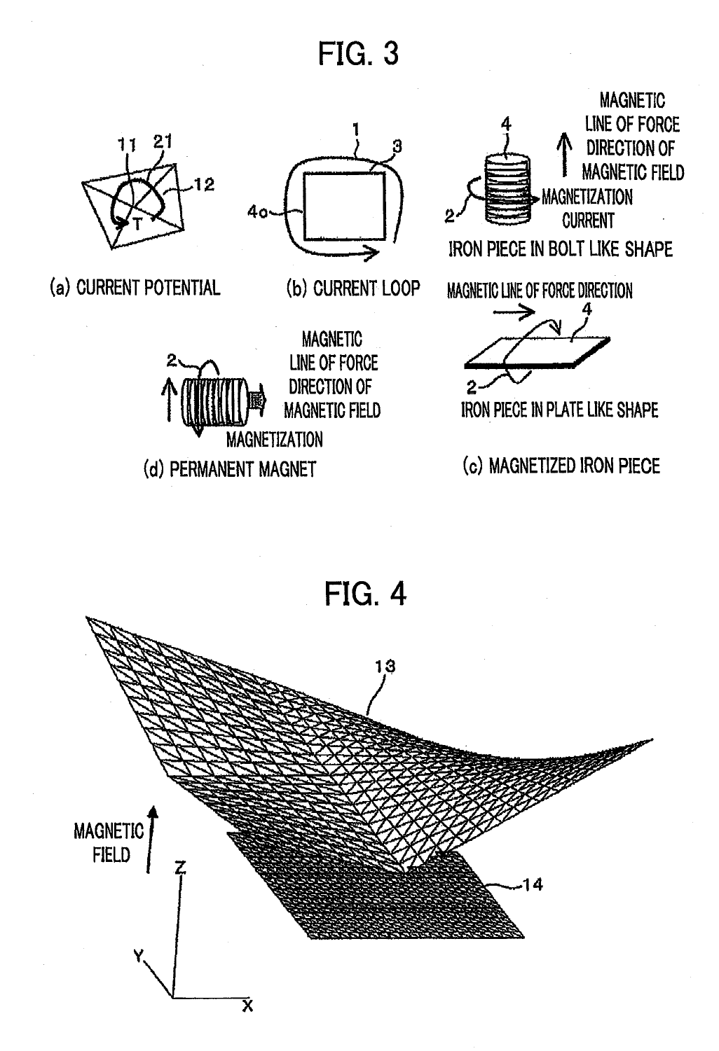

FIG. 3 is a drawing illustrating equivalence among a current potential, a current loop by a small coil 3 (current loop 4c), a permanent magnet piece 4p, and equivalency of a magnetized iron piece. As an iron piece 4, shapes of a bolt and a plate are shown. In addition, a magnet, which is not an iron piece, is equivalent through a magnetization current 2 on the surface, in which case a direction of the magnetization current 2 is determined by magnetization of the permanent magnet 4p irrespective of a circumferential magnetic field. Here, the iron piece is described. However, the iron piece can be replaced with a material as long as the material is a ferromagnetic. Hereinafter, this will be referred to as an iron piece simply.

FIG. 3 (a) shows a finite element 12, a node 11, and a current 21 caused by a current potential T for calculation. FIG. 3 (b) shows a magnetic moment generation by the current 1 flowing through a small coil 3. FIG. 3 (c) shows a magnetic moment by the magnetization current 2 by the magnetized iron piece 4. The shape of the bolt is shown on the upper side, and the shape of the plate is shown on the lower side. They are considered to be equivalent to a permanent magnet which is not a magnetic member possibly magnetized such as iron, but is voluntarily magnetized, if the magnetization current is adjusted in accordance with an extent of magnetization. However, in the case of the permanent magnet, there is a magnetization direction irrespective of circumferential magnetic filed as shown in FIG. 3 (d), and there is also a magnetization current. As shown in FIG. 3 (a), if the current potential T has a certain value at a node 11, this can be understood such that the current 21 rotationally flow between nodes around the current 21. In other words, this is equivalent to a situation in which the current 1 flows through the current loop of the small coil 3 in FIG. 3(b). In addition, this is equivalent to a situation shown on the right side where the magnetization current 2 which is jₘ (A/m) flowing on a surface of the magnetized iron piece 4. In other words, the current potential value T used for expressing a current distribution by DUCAS has a dimension of [A] as unit. However the current potential value T can also be considered to have a dimension of [A] because of a density [1/m²] of the magnetic moment [Am²]. On the other hand, the iron piece 4 sufficiently magnetized has a magnetic moment proportional to a volume thereof because the magnetic moment is in proportion to a product of an area surrounded by the magnetization current and a length in a direction of the magnetic force line. In other words, the current potential T when the magnetic field adjustment is done, is a quantity proportional to a density of the iron piece 4 [weight per a unit area, i.e., g/m² or a volume cc/cm²]. This characteristic is used, and an eigen-distribution function and a singular value, obtained by the singular value decomposition, used in DUCAS in place of the spherical harmonic function which is a conventional method, are used.

According to this, an apparatus is provided which conducts, using DUCAS, a support calculation for adjusting a magnetic field in which a magnetic field generating apparatus is a target and which displays an arrangement of the iron pieces for the adjustment or an arrangement of the magnetic moment. An operator can do adjustment toward a target magnetic field distribution by advancing the adjustment in accordance with the display.

The present invention allows a given magnetic field distribution to be a target magnetic field. However, argument is mainly made with assuming that the target magnetic field is uniformly homogeneous. However, whether the target magnetic field has a distribution does not affect the argument below. This is simply provided to make it easy to understand the argument.

The error magnetic field Bₑᵣᵣ (\vec{r}) is a function of position, but is considered to be a combination of the eigen distribution functions in the present invention. That is,

Bₑᵣᵣ(\vec{r})=ΣCₘψₘ(\vec{r}) (1)

In the conventional method, Legendre polynomial or spherical harmonic functions is used. In the present invention, a distribution function by the singular value decomposition is used. Will be described a way of determining the function ψₘ to be summed and its coefficient Cₘ more specifically.

In the argument of the present invention, a system shown in FIG. 4 is considered as a general system. FIG. 4 shows a calculation system of the present embodiment. It is formed with a current potential evaluation plane 13 and a set 14 of magnetic field measurement evaluation nodes. Generally, there may be a case where a plurality of current potential evaluation planes 13 exist, but the argument is made with assumption that there is one current potential evaluation plane 13 here. In addition, the magnetic field evaluation nodes do not always form a plane, but the magnetic field evaluation nodes are shown as points on a plane.

A measurement point j has three-dimensional magnetic field components Bₓⱼ, B_{yj}, B_{zj}. In the measurement at a point, the measured magnetic field components are shown with the position and a unit vector p defined at the position. There may be a case where there are three pieces of data although the number of points in a space is one.

In addition, when a homogeneous magnetic field is obtained like the MRI device, only main component in an axial direction of the magnetic field is made constant. This is because although it is important that an intensity of the magnetic field is constant in the MRI, the main component of the magnetic field is approximately equal to an intensity of the magnetic field, because components other than the main component are very weak.

In the error magnetic field that is a difference between the measured values and the target magnetic field, there are a plurality of pieces of measured data, and the whole of the pieces of the measured vector being represented as \vec{B}ₑ. The error magnetic field Bₑ is a difference between the measured magnetic field Bₘ and a magnetic field intensity B_{tg} for adjustment to have a homogeneous magnetic field.

An error magnetic field corresponding to the measurement point j is \vec{B}ₑ having components of Bₑⱼ and is given by:

Bₑⱼ=B_{tg}−Bₘⱼ (2)

A general system, to which singular value decomposition is applied, is as shown in FIG. 4. There is a region of evaluation nodes of the magnetic field, and the magnetic field is measured at the evaluation nodes. The iron pieces for adjusting the magnetic field are arranged on a CSS plane. The plane is called a shim-tray in the MRI.

Will be described a relation between an iron density and error magnetic field correction. The plane is divided into triangle elements and a current potential is assigned to the node. This is described in the non-patent document 1. A relation between a magnetic field vector having the measurement data as an element at the evaluation nodes of the magnetic field and the current potential vector having the current potential on the CCS plane as an element is given by:

\vec{B}= [symbol] ·\vec{T} (3)

This equation represents a response of the magnetic field at the evaluation node of the magnetic field from a vector \vec{T} having a current potential value at a node on a current plane as an element. Matrix [symbol] is m (the number of the measurement points of the magnetic field) rows and n (the number of nodes) columns.

A set of an eigen-distribution function of a magnetic field distribution and a current potential is obtained by effecting the singular value decomposition on a response matrix A¹ to the magnetic field evaluation node from a current potential at an isolated node obtained by adding a constraint of a node to the matrix A. That is, it is a set of eigen-distributions:

\vec{u}₁,\vec{u}₂,\vec{u}₃ (4)

, which is a base of the magnetic field distribution and eigen-distributions:

\vec{v}₁,\vec{v}₂,\vec{v}₃ (5)

, which is a base of the current potential, and there is a relation between \vec{u}ⱼ and \vec{v}ⱼ given by:

λⱼuⱼ=A·vⱼ (6)

Here, λⱼ is a singular value. Further, the subscript j is the number of order in which a number is assigned to each eigen distribution in magnitude order of the singular values. Each of base vectors indicating the current potential distribution and the magnetic field distribution corresponds to one number. It is assumed that two base vectors relating one number and one singular value are referred together to as one eigen-mode. Further, the ordinal number j is a number of order of the eigen-mode.

It can be said that a low-numbered eigen-mode which has a large singular value can generate a large magnetic field intensity as it is understood that a magnetic field intensity per a unit current potential distribution vⱼ is λⱼuⱼ. On the other hand, when a current potential is varied in an eigen-mode having a small singular value, a change in a distribution of the magnetic field is small. This characteristic, which will be described later, will play an important role in this magnetic field adjustment method. As the distribution function defined by Eq. (1) the distribution of an eigen vector obtained by the singular value decomposition is used.

Will be described a correction method or adjustment method (reduction of the error magnetic field by shimming) of the error magnetic field corresponding to the eigen-mode having an order number j. A coefficient Dⱼ indicating what times as large as the base current potential distribution \vec{v}ⱼ can be obtained from the error magnetic field distribution. The magnitude is given by:

Cᵢ=\vec{B}ₒ·\vec{u}ⱼ (7)

Dⱼ=−Cⱼ/λⱼ (8)

In other words, an error magnetic field of j-^{th} eigen-distribution can be perfectly corrected by giving a current potential distribution Dⱼ\vec{v}ⱼ.

Next, will be described a relation between the current potential and an iron piece density. The iron piece can be replaced with a magnetic moment in consideration of a magnetization current on a surface thereof. A magnetization current jₘ (A/m) on a surface of the iron piece is given by:

jₘ=M/μ₀ (9)

Here, M means a magnetization (T). When the iron piece is in a saturation status, M is about 2.1 T. Accordingly, jₘ is about 1.7×10⁶ A/m. Accordingly, iron having a volume of one cubic meter has a magnetic moment of about 1.7×10⁶ Am² (170 Acm²/1 cc). Because this value depends on a kind of a magnet and particularly on the magnetic field intensity, it is necessary to make consideration for each case. However, in the magnets having a magnetic intensity exceeding approximately 1 T, it is natural that the iron piece is magnetized in a status near saturation. In this status, the magnetic moment of iron is proportion to a volume of the iron piece.

In this conversion, in order to cancel out the error magnetic field of j-^{th} eigen-mode, an iron piece is arranged with a volume density (m=m³/m²) corresponding to a component dⱼₖ of \vec{d}ⱼ (an iron volume at k-^{th} iron piece correction node corresponding to j-^{th} eigen distribution function).

dⱼ=−vⱼCⱼ/(λⱼjₘ) (10)

Further, in a case where the magnetic field is corrected by arranging a current given by (∇\vec{T})×\vec{n} in which is vector \vec{j} is a vector product of the current potential \vec{T} and a normal vector on a surface.

The above-mentioned method is a basic method of correction. This is correction of components by the eigen distribution (\vec{u}ⱼ) of an error magnetic field. The correction according to the present invention features that the distribution functions (\vec{v}ⱼ, \vec{u}ⱼ) are basis, respectively, and correspond to each other one by one. To correct one of the eigen-distribution components, a distribution function of only on adjusting means is adjusted.

Even in the method according to the present invention, there are many eigen-distribution functions of the error magnetic field to be corrected. The above-mentioned method is expanded to a selecting method of the eigen-mode to be corrected from many eigen-modes and the correcting method. A basic way of considering this has the following items:

(1) It is selected from the eigen-modes which can correct a large magnetic field with a small current potential (i.e., with a small volume of iron piece). An index used for this selection is a singular value λⱼ. Because the singular value is a magnetic intensity per a unit current potential for each eigen-distribution in this calculation system, the eigen distribution having a small singular value is not selected. In other words, it is also can be said that the singular value is a value which is proportional to a magnetic field intensity per a unit iron volume. Generally, because it is desired to generate a homogeneous magnetic intensity with a small volume, an eigen distribution having a large singular value is used for adjustment.

(2) One having a small component intensity of the eigen magnetic field distribution included in a measurement magnetic field is negligible. If a component intensity calculated in an inner product (Eq. 7) is an intensity sufficiently smaller than an allowed error magnetic field at a target homogeneous magnetic level, further correction is not necessary. When the eigen component has a small component intensity although the eigen distribution has a large singular value, it has a large singular value, it is not selected because it is not necessary to be used in shimming.

(3) An eigen-distribution function is selected individually which the operator particularly determines to be necessary for correction, and it is corrected with an intensity obtained by the inner product or an intentionally determined intensity. For example, in a case where a locally large error magnetic field occurs because peaks of the error magnetic field distributions are overlapped, correction by correction of intentionally decreasing peaks is conducted by selecting a proper eigen-distribution function with a proper magnitude.

(4) A homogeneity (attainable homogeneity) after the current potential component of the selected eigen-distribution function is corrected, is obtained and it is determined whether the selection of the eigen-distribution function is proper. If the attainable homogeneity is insufficient, the selection of the eigen-distribution function is considered again. The homogeneity is a difference in magnetic field intensity between the maximum and the minimum among the plurality of measurement points in the magnetic field evaluation region, in other words, the homogeneity indicates a ratio of the peak-to-peak difference in the error magnetic field with respect to an average magnetic field and is generally argued at an order of one millionth (ppm) in the MRI.

(5) When the target magnetic field is changed, because an intensity of each eigen-distribution included in the error magnetic field and an intensity of the magnetic field left as a residual difference, i.e., the homogeneity, changes, it is necessary to consider the target magnetic field in selecting the eigen-distribution.

(6) Adjustment is carried out by repeating operation from several to tens times. That is, an accuracy of the magnetic field is increased because an accuracy of adjustment mechanism is generally coarser than the accuracy of the magnetic field to be a target. For example, in shimming in the MRI, it is necessary to conduct the magnetic field adjustment with an accuracy of one micro tesla, however, the error magnetic field before shimming is around several milli-teslas. When this is adjusted at one trial, it is required to control the iron piece to be arranged for the adjustment in volume at a fine accuracy equal to or smaller than 1/1000. Then, according to the present invention, at the first adjustment, the error magnetic field is decreased at an accuracy in control volume equal to or smaller than approximately 1/10 and the error magnetic field is decreased in accordance with the number of times of adjustment. Accordingly, a relative ratio with the final magnetic field accuracy is decreased to provide a sufficient final accuracy in the magnetic field even with a volume control of equal to or lower than 1/10.

Next will be described a relationship between the iron piece arrangement and the above-mentioned description in consideration of the case where the shimming is conducted with the iron piece. A correction quantity \vec{D} corresponding to the selected eigen-distribution is a sum of correction volumes \vec{d}ⱼ by the respective eigen-distribution functions and is given by:

\vec{D}=Σ\vec{d}ⱼ=Σ−\vec{v}ⱼCⱼ/(λⱼjₘ) (11)

where the sum of Σ is conducted with respect to the eigen-distribution functions selected. It is easy to predict through calculation how the magnetic field distribution in the imaging region after conduction of the correction becomes.

There is one method in which it can be obtained from functions of the eigen-distribution functions of the magnetic field distribution. It is given by:

\vec{B}ₛₕᵢₘ=\vec{B}ₑΣCⱼ\vec{u}ⱼ (12)

where the sum Σ is conducted for the selected eigen-distribution functions.

The other is a method reconstructed with the current potential reconstructed. A correction Δ\vec{T} of the current potential in Eq. (12) is given by

Δ\vec{T}=Σ−\vec{v}ⱼCⱼ/λⱼ (13)

The error magnetic field distribution after correction is given by:

\vec{B}ₛₕᵢₘ=\vec{B}ₒ− [symbol] Δ\vec{T} (14)

These two methods provide the same calculation results. Here, the sum Σ is conducted for the selected eigen-distribution functions. By the calculation method, the attainable homogeneity after the magnetic field adjustment is predicted to determine whether the magnetic field adjustment advances in a target accuracy of the magnetic field adjustment.

The determination is carried out with reference to the iron volume necessary for shimming in addition to the attainable homogeneity. If an excessive iron piece is necessary, the selection of the eigen-distribution functions is considered again. If calculation of all selections provides that an excess volume of the iron pieces is necessary, it can be determined as a magnet with poor magnetic design or poor manufacturing.

This function is applicable to:

(a) quality assurance of magnet product; and

(b) consideration whether a design of arrangement of electromagnetic forces is proper and whether reconsideration of arrangement is necessary or not. A necessary volume of the iron paces is approximately 170 Acm²/1 cc as argued in relation to the equation (9) and can be converted. In addition, a magnetic moment necessary for correction is obtained by a surface integration by:

∫Tds=ΣTiΣSij/3.0(Am²) (15)

where an integration region will be descried in an actual example. In addition, because a discrete indication is calculated with division into meshes, it indicates an actual calculation content. The sum Σ attached at the front part is performed at a node i within the integration region. Sij is an area of an element j belonging to i-th node. Because it is a triangle element, it is considered that one third of it contributes to the i-th node. The sumΣ attached reward is carried out regarding the triangle element j to which an i-th node. Hereinafter, simply described as follows:

Si=ΣSij/3.0 (16)

The argument described above is made in which the current potential is a variable. However, the area Si participating in the nodes is considered from the beginning and a conversion will be carried out as follows:

TiSi→Mi (17)

Then, it becomes an argument treating an intensity of the magnetic moment Mi. The argument so far described only conversion of the area with a magnification of only a size, and the argument using the singular decomposition becomes the same. In this case, the integration of Eq. (16) becomes a sum of magnetic moments simply belonging to the area. In addition, when calculation of Eq. (16) is carried out from Eq. (1) with the magnetic moment Mi being as a variable as mentioned above, the position of an arrangement of the magnetic moment is not limited to on-surface such as the current potential. However, an outline configuration of the magnetic field adjustment mechanism used in an actual shimming operation is a flat plate or sleeve surface. Then, argument will be made in which current potentials are on a curved plane.

Operations of the improved items in the present invention will be described.

In the selection of the Eigen-mode in the item of (1) is selected to correct the error magnetic field with respect to low-numbered eigen-distribution functions. A low-numbered distribution function is selected within a range of compensating correction for the magnetic field with a small quantity of iron piece. Even if only low-numbered distribution functions are selected, generally, tens to hundreds eigen-distribution functions are selected. By correcting the magnetic field in accordance with the arrangement of the iron piece (current potential) arrangement with the eigen-distribution functions, correction can be done without a large affection or a new error magnetic field to the not-selected eigen-distribution. This provides an advantageous effect in avoiding disturbance of high-order components (eigen-distribution numbered with high order) which were not selected. In other words, when the magnetic field adjustment is conducted, the operation does not become complicated because the non-selected high order eigen-distribution becomes disturbed.

The low-numbered eigen-distribution functions selected by the singular value decomposition can be corrected with a low volume of the iron piece, but a larger volume is necessary to vary the high-numbered eigen-distribution functions. The reason why the high-numbered part is not disturbed is that a large value of the iron piece is necessary for changing the high-numbered eigen-distribution functions in addition to that the distribution is orthogonal. More specifically, correction for the low-numbered distribution function which needs a small volume of iron piece does not result in change in an intensity of a high-numbered component even if the arrangement is disturbed regarding the error. Also for this reason, the eigen-distributions are selected from the low-numbered eigen-distributions.

In addition, because a magnetic field of low-numbered components that can be corrected are large in proportion to the singular value, the magnetic field adjustment, i.e., shimming, can be done with a small volume of the iron piece efficiently.

In the item (2), the eigen-distribution function for which the correction is not necessary is not corrected. However, if it is included in the adjustment volume by selection, because a magnitude of adjustment volume is small, it does not disturb the high-numbered components as mentioned above, and thus there is no problem.

The item (3) is adjustment of selection between the iron arrangement amount and the magnetic field distribution. In a case where the magnetic field is corrected with only iron piece, there may be a case where an adjustment by a negative volume of iron piece, i.e., removing the iron piece, is difficult to be conducted. On the other hand, arrangement of the iron piece for a high-numbered distribution generates a small magnetic field. In other words, arranging an iron piece for a high-number component provides a space for removing an iron piece in correction for the low order. In addition, if the homogeneity is defined within a range from a positive peak value to a negative peak value, there may be a case where an indication of the homogeneity becomes worse particularly at the peak part concentrically. In this case, a proper correction component is intentionally added. This allows the homogeneity to reach the target. Here, the negative volume of the iron piece corresponds to the case where the magnetic moment necessary for the magnetic field adjustment obtained by Eq. (15) shows a magnetic moment having a direction opposite to the direction of magnetization by the iron piece by the circumferential magnetic field. This correction is possible by using a current loop or a permanent magnet other than the method described above. However, this invites a complication in procedures and configuration. Accordingly, if possible it is desirable to cope by the above-described procedure.

The item (4) enables checking whether the magnetic field can be adjusted at a target accuracy. When the magnetic field is corrected with respect to the selected eigen-distribution functions, it is necessary that the homogeneity finally reaches a target by repeating the correction. This method provides prediction as to what homogeneity can be obtained by the calculation method mentioned above. In accordance with the prediction, it is determined whether the selection of the eigen-distribution functions should be changed. In a case where only low value of the homogeneity can be obtained, it can be determined that the quality is problematic because there is a problem in production. The problem in quality may frequently occur at the high-numbered components, in which case it is difficult to conduct correction. On the other hand, in the method of the present invention in which the components are divided by the singular value decomposition, it is easy to discover a problem occurring at the high-numbered eigen-modes.

The item (5) is to select a setting intensity of the magnetic field intensity to be homogeneous. The eigen-distribution functions are selected while the target magnetic field is changed, and an attainable homogeneity and the volume of the iron piece are checked. Then, a target magnetic field is selected to have a good homogeneity and an easy arrangement of the iron piece. Easy arrangement of the iron piece is not that the volume is small, but that an arrangement allows a relative-low-number distribution functions to be sufficiently corrected and has no region where the iron piece having a negative volume value is arranged.

The item (6) completes the magnetic field adjustment by repeating the operation from the measurement to the arrangement of the iron piece. Depending on a geometrical arrangement subject to the magnetic field adjustment, there is a difference in a magnitude of the singular value selected of about four figures between the selected low-numbered singular value and the selected high-number singular value at the maximum. In other words, adjustment varies in accordance with the selection of the eigen-distribution functions from an adjustment in which a volume of about 100 cc is handled in the magnetic adjustment to an adjustment in which a volume of 0.01 cc is handled. On the other hand, it is not easy to control the adjustment with an accuracy in which 1/10 of iron piece is handled. Then, the adjustment is repeatedly done to correct the residual error in the magnetic field, so that even if every adjustment has only 1/10 of accuracy, a final accuracy can reach a good homogeneity. During repeating, at a first stage, eigen-distributions up to high-numbered eigen-distributions are selected to do an adjustment for a larger volume and then, an upper limit of the order is gradually decreased. When the number of the order is decreased, it is confirmed that a high-numbered part has been sufficiently corrected. In addition, as the number of order is decreased, the volume as the result of the calculation for correction decreases. Accordingly, the adjustment accuracy of about one tenth of the volume will increase.

The magnetic field adjustment is conducted repeatedly. Here, as described with respect to the item (2), the high-numbered eigen-modes not selected are not disturbed. Accordingly, the homogeneity predicted does not vary during repeating.

As mentioned above, according to the method of the present invention based on the eigen-distribution functions obtained from the singular value decomposition of the response matrix from the current potential on the shim-tray to magnetic field intensities at magnetic field evaluation nodes placed on the imaging region, the target magnetic field homogeneity can be obtained with a low adjustment volume for the error magnetic field in which the magnetic field after adjustment is being predicted. Shimming operation should be repeated. In addition, during a repeating operation, when the shimming is conducted, particularly for high-numbered distribution, there is a case where the homogeneity apparently becomes worse because error magnetic field components corresponding to a low order distribution functions increases. On the other hand, the method also has an advantageous effect in that it is confirmed how the magnetic field adjustment advances by confirming component intensities of the eigen distribution functions, which results in that components on the side of high orders selected are corrected. This is advantageous to the operator in confirming appropriateness of the operation. In addition, there is an advantageous effect in that the adjustment is advanced with easiness feeling because it is confirmed that the magnetic field adjustment for a manufacturing error up to the target accuracy is not impossible because the homogeneity attainable at an end of adjustment can be grasped.

### FIRST EMBODIMENT

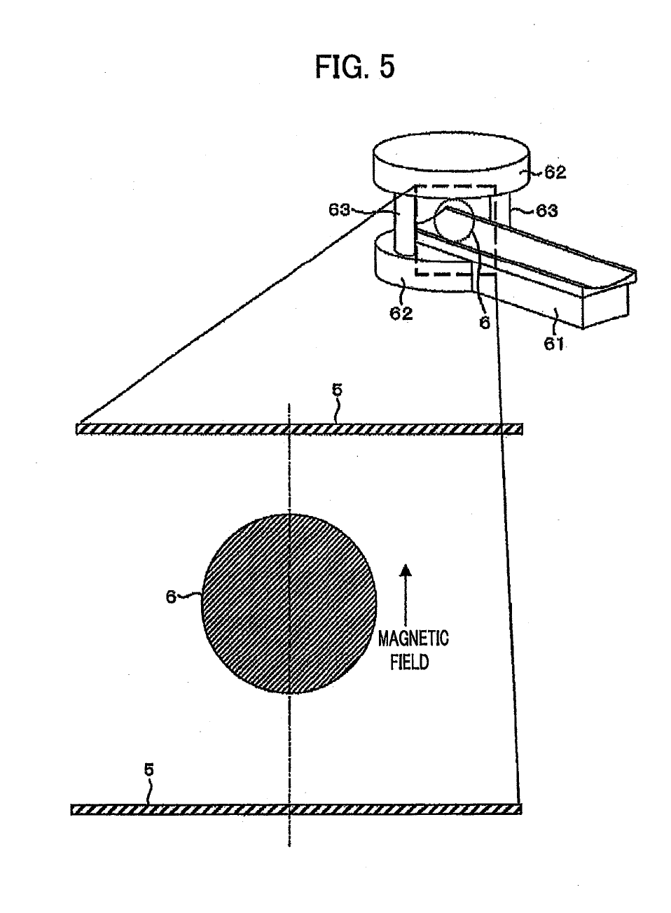

Will be described a first embodiment. Application to the magnetic field adjustment (shimming) in an open type MRI device having a vertical magnetic field will be described as the first embodiment. FIG. 5 shows a system of the magnetic field adjustment (shimming) for a magnetic field generated by a magnet of the MRI device in FIG. 5. This drawing is made with supposing an open type in which a direction of a magnetic field (line of magnetic force) is directed to a vertical direction. A conception shape of an open type MRI magnet is shown in a drawing of FIG. 5. There are magnet devices 62 divided in a vertical direction and connecting columns connects them therebetween.

Inside them, there are a vacuum vessel 62c for securing vacuum for thermal insulation, a radiation shield 62d, a cryogenic temperature vessel 62e, and coil groups 62a including a magnetic filed shielding coil 62b. A person to be inspected lies on the patient bed 61, and a nuclear magnetic resonance tomography is carried out.

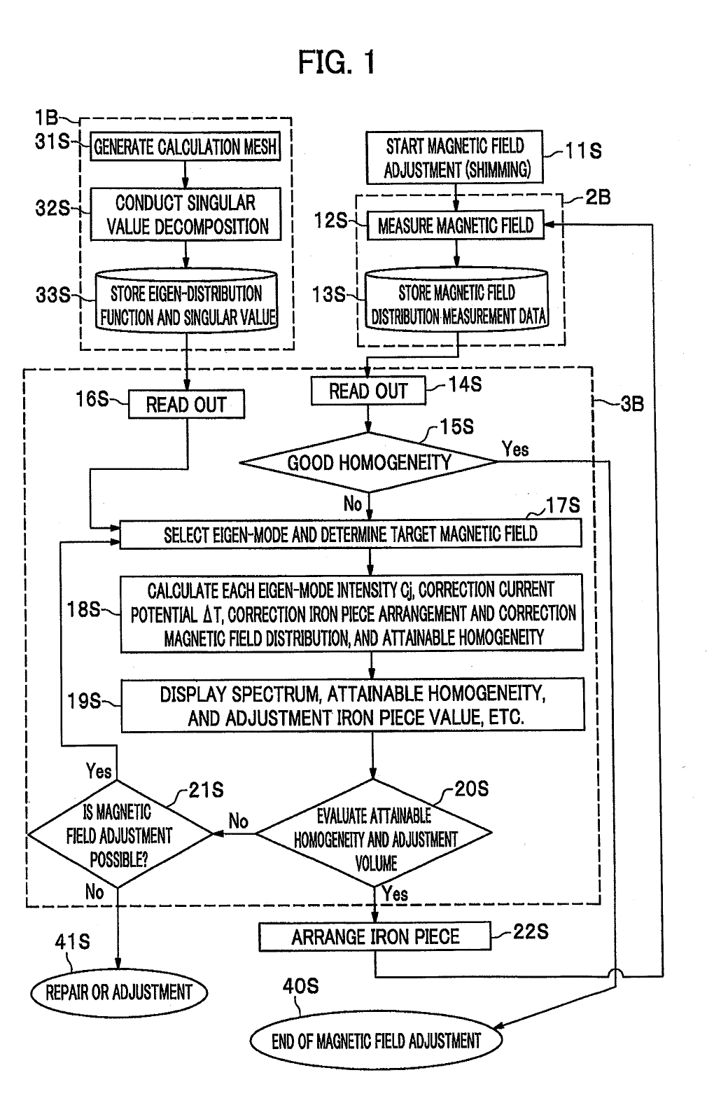

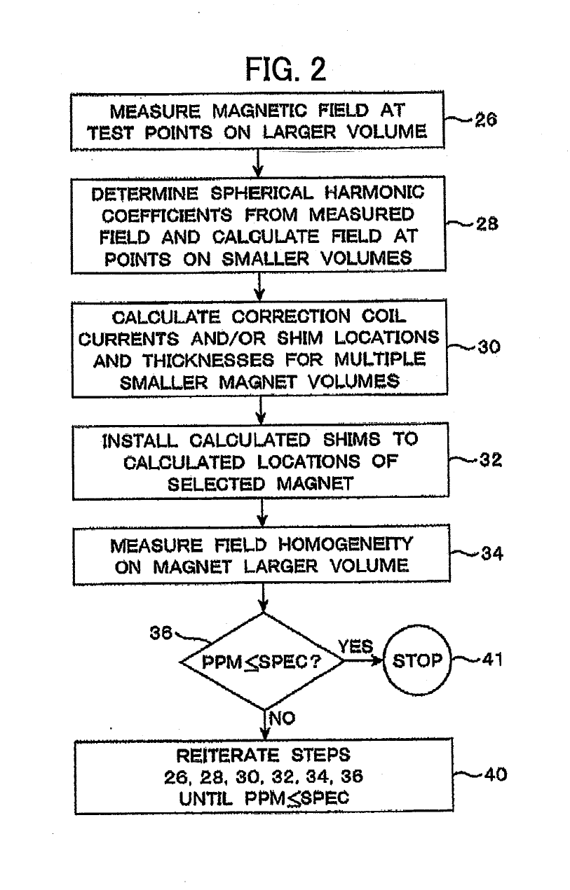

There is a space (magnetic field measurement evaluation region) 6. The magnetic field distribution at magnetic field evaluation node on a surface thereof or an inside surface thereof is adjusted (shimmed) to be homogeneous. FIG. 1 shows a flowchart of shimming for adjusting the magnetic field distribution in the first embodiment. This is an embodiment where this is applied to the magnetic field adjustment in an imaging region of the open and vertical magnetic field type of MRI device. An intensity of magnetic field component is vertical to a ground surface. There are magnetic field adjusting mechanism planes (shim-trays 5) above and below the imaging region, and iron pieces 4 are arranged on the magnetic field adjusting mechanism planes.

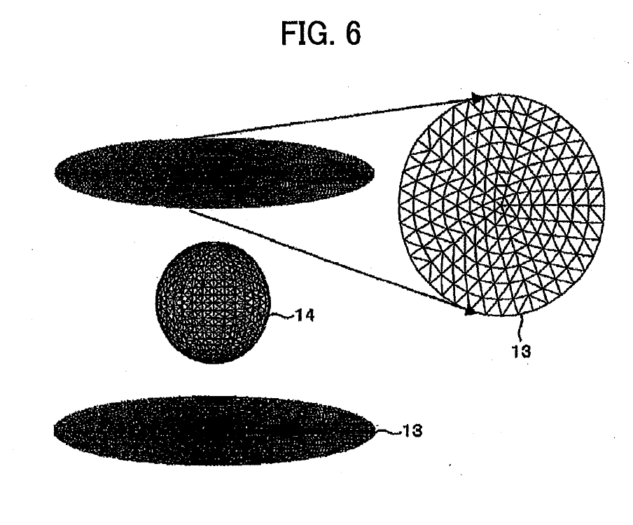

FIG. 6 shows an example of mesh generation when the first embodiment is applied to the shimming in the MRI device. In the first embodiment, there are hundreds of magnetic field measurement points are arranged as a set 14 of the magnetic field measurement points on a surface of a sphere. Circular disk planes above and below the sphere are calculation models of the planes where the iron piece(s) 4 are arranged when shimming is carried out, i.e., current potential evaluation surfaces 13. As roughly shown by finite elements on the right side of the drawing, a system of finite element calculation including triangle elements with nodes on the plane is formed.

A pre-calculation part 1B inside a broken line in FIG. 1 is calculated before a shimming work process. It includes a singular value decomposition calculation step 32S, a calculation mesh generation step 31S, a storing step 33S of the eigen-distribution function and the singular value as the result of the singular value decomposition. This part is a pre-calculation part 1B including the singular value decomposition of a response matrix A from nodes corresponding to current potential values at thousands of points to magnetic field measuring points of hundreds in the imaging region, and thus needs a relative long calculation period. Therefore, the eigen-distribution functions are calculated for shimming through the calculation system matched to a system of magnet to shorten a calculation time period of the shimming work process.

The data previously calculated is stored in a storage region of a computer by the storing step 33S. The data is read out (reading out step 16S for the singular value decomposition result) as needed, and used. In other words, in the computer, the more than several eigen-distribution functions which are base vector groups of magnetic field distribution, the same number of base vector groups which are distribution functions on a current plane, and the same number of singular values which are conversion information therebetween in magnitude, are combined and stored.

After a certain time elapses after excitation of the magnet, a step of starting the magnetic field adjustment (shimming) 11S is done. The magnetic field adjustment work process is carried out in accordance with the flowchart in FIG. 1. A magnetic field measurement step 12S is conducted. After a magnetic field distribution data storing step 13S and a magnetic field data reading step 14S, it is determined whether the homogeneity is good in a magnetic field homogeneity determining step 15S. If the homogeneity is sufficient, the shimming is not necessary, the work process progress to a magnetic field adjustment completion step 40S. This can occur in a case where an apparatus used with a sufficient homogeneity is re-excited after de-magnetization on maintenance. On the other side, in a case of a new magnet, due to a manufacturing error, the homogeneity is from about hundreds to thousands ppm. In this case, it is determined that the magnetic field adjustment (shimming) is necessary.

Then, the process moves to a step S17 of eigen-mode selection and determination of a target magnetic field. In the next step 18S, Eqs. (1) to (14) for each eigen-mode intensity Cj, adjustment current potential Δ\vec{T}, adjustment iron piece arrangement, and adjustment magnetic field distribution, and attainable homogeneity, are calculated for the selected eigen-mode.

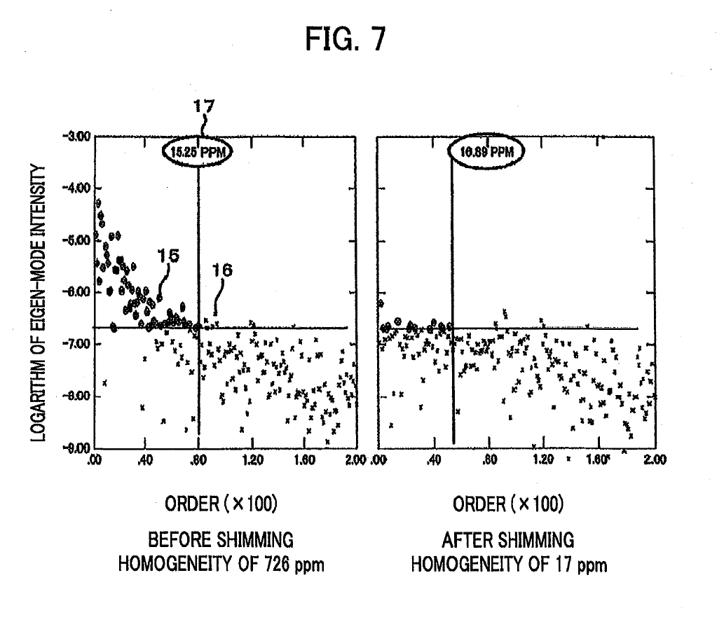

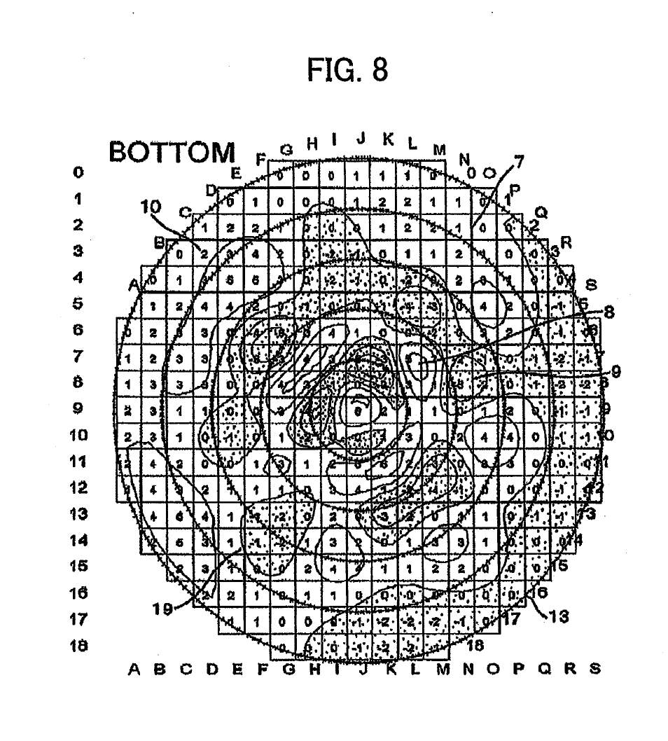

Next is a display step 19S for determining appropriateness of selecting the eigen-mode. A calculation result in the step 18S is displayed to determine appropriateness of selecting the eigen-mode. There are two display modes. One is shown in FIG. 7 and the other is shown in FIG. 8.

FIG. 7 is a chart showing eigen-distribution intensity along a vertical axis and the number of order of the eigen-mode, of the magnetic field included in the error magnetic field obtained by an equation such as Eq. (7) and called spectrums. The vertical axis is shown in a logarithm scale. FIG. 7 also shows a range of selecting an eigen-mode and the attainable homogeneity. In addition, FIG. 8 shows a display example of an iron piece arrangement volume for shimming work process with current potential contour lines.

The detail of calculation explained in this example is shown in FIGS. 5 and 6. It is assumed that magnetic field evaluation points are on a surface having a diameter of 40 cm. A target is to make the error magnetic field equal to or smaller than 20 ppm on this surface.

With reference to vector expression in FIG. 7, one of eigen-distribution functions to be corrected is selected. In FIG. 7, a mark “x” corresponds to the individual eigen-mode, and a mark “o” corresponds to the selected eigen-mode 15. Eigen-modes not marked with “o” are not-selected eigen-mode 16. The selection is done by the method mentioned earlier. When the distribution function to be corrected is selected, an attainable homogeneity can be calculated for prediction by subtracting the error magnetic field component from the measured error magnetic field. In FIG. 7, the attainable homogeneity 17 is shown with a mark of an oval.

FIG. 7 shows two charts of spectrum, in which FIG. 7 (a) shows that before shimming and FIG. 7 (b) shows that after shimming. The homogeneity before shimming is 726 ppm, and it is understood that low-numbered error magnetic field components are large in the chart of spectrum. The eigen-modes marked with “o” have orders of which the number is equal to or smaller than 80 and are eigen-modes selected as error magnetic field components having intensities above about low limit of a measurement accuracy. In this example, the attainable homogeneity is predicted at 15.25 ppm when the selected eigen-mode is corrected. A line 22 indicating an upper limit of the order for selecting the eigen-mode is displayed and a line 23 indicating a lower limit of intensity is displayed on the chart of spectrum in FIG. 7, and then the eigen-mode is selected on the chart of spectrum in FIG. 7.

When the attainable homogeneity predicted is insufficient, the selection of the eigen-distribution function is considered again. The number of eigen-distribution functions is adjusted, i.e., upper and lower limits of the number of an eigen-distribution functions selection range and a lower limit of the eigen-mode intensity Cⱼ are adjusted. In addition, there is another option of adjusting a correction ratio of the eigen-distribution functions selected individually.

Another display in the step 19S is used for checking whether shimming is possible in an instruction chart of the iron arrangement volume shown in FIG. 8. A circle in FIG. 8 shows the shim-tray 5 shown in FIG. 5. There are two shim-trays. However, FIG. 8 shows the lower shim-tray. Meshes 7 in the chart are sections arranged on the shim-tray 5 and an address is allocated to each mesh. In FIG. 8, an address is specified with A, B, C, . . . in right-left direction and with 1, 2, 3, . . . in up and down direction. A value in a mesh 7 indicates an iron volume 18 to be arranged on the mesh 7. In FIG. 8, a unit is 0.1 cc. The structure allows an iron piece of about 5 cc to be arranged on a mesh. The displayed volume is sufficiently small, which allows the iron piece to be arranged. During the repeated adjustment, the volume of the iron piece to be handled becomes small gradually. Accordingly, it is displayed with smaller units of 1/10, 1/100, and 1/1000.

In FIG. 8, contour lines 19 are shown in addition to the meshes 7 and iron piece volume 10 at a mesh on the current potential evaluation plane 13 which is obtained by modeling the shim-tray 5. When the current potential contour lines 19 are considered to be in a coil shape, the error magnetic field can be adjusted with a coil having this shape. This is described in the published paper mentioned earlier. The contour line display according to the present invention provides another advantageous effect. The distribution functions obtained by the singular value decomposition require arrangement of the iron piece or a magnetic moment with spreading on the surface. However, the distribution function requires arrangement (or removal) with a most volume around a peak 8 of the contour line and a valley 9 of the contour line. Using these two characteristics, an iron piece arrangement location for the magnetic field adjustment is flexibly considered. If there is no limitation in arrangement or removal, iron volumes inside a current potential contour line 19 closed with the same sign around a peak of the contour line are added, and the added volume is arranged or removed around the peak 8 of the contour line. In addition, if it is impossible to arrange the iron piece because, for example, a supporting member for the shim-tray around the location exists, it is possible to arrange (or remove) the same volume of the iron piece at another part within the same closed contour line region. The peak 8 in FIG. 7 is between lines of L and M and lines of 7 and 8. On the meshes around a cross part of lines L and M with the lines of 7 and 8, a total volume of 5+3+2+1=11 is required to be arranged. Then, according to the present invention, it is good that the iron piece of the volume of 11 is arranged at the peak 8 of the contour lines at a cross of the lines between L and M with the line between 7 and 8. Such an arrangement reduces a work quantity and provides relaxation in the arrangement position accuracy with facilitation of the work process.

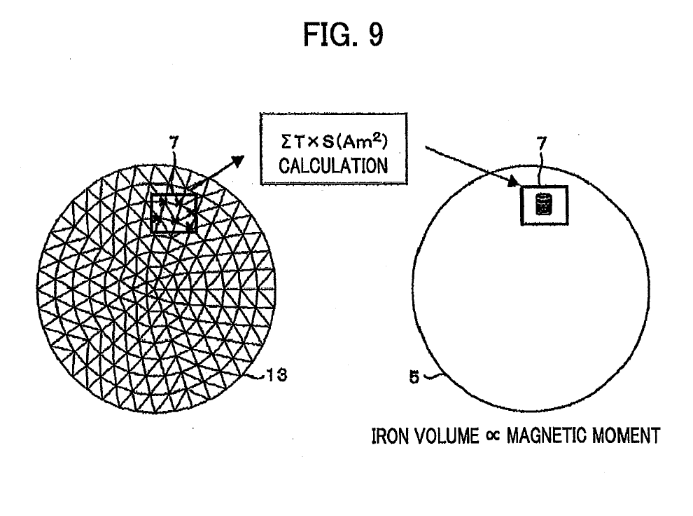

With reference to FIG. 9, will be described a method of calculating the magnetic moment or the iron volume within the mesh. FIG. 9 shows concept of conversion from a node potential value into the magnetic moment, and the iron volume. It has already been described that the volume of the iron piece is proportional to the magnetic moment at the description following Eq. (9). In addition, it can be understood that the current potential represents the magnetic moment per a unit area. Then, to obtain a volume of the iron piece at a region, the current potential T is subjected to surface integration in the region. A magnetic moment is considered as a magnetic moment necessary at the region and is converted into the iron volume as mentioned earlier. FIG. 9 schematically shows a relation between the mesh 7 and a node shown in FIG. 8. A point indicated by “x” is the node. Because they are not continuous functions, for example, a product of a node and areas corresponding to the node are added as shown by an equation in FIG. 9 and is assumed as the magnetic moment. There is a method of obtaining an area corresponding to the node by that an element belonging to the node area corresponding to the node is divided into ⅓ (in the case of Δ element).

A comment is made on a dimension of the mesh 7 and an element size on calculation. Regarding a size of the mesh 7, a fineness is required which has a resolution capable of showing the iron piece arrangement distribution shown in FIG. 8. A contour line distribution near an upper limit of the order of the eigen-mode necessary to obtain homogeneity is confirmed to make the size smaller than sizes of the peak and the valley. On the other hand, making the size of the mesh small requires more processes. In FIG. 8, the size is approximately the same as a minimum size of the peak 8 of the contour line and the valley 9 of the contour line. Because the sizes are approximately the same, at a part where the contour lines are fine, there may be a place having an insufficient resolution only with the meshes 7. In this case, the iron piece is arranged with adjusting a place to which the iron piece is arranged with reference to the peaks and valleys of the contour lines. A size of finite elements is determined by the number of the nodes within a mesh. As previously mentioned, an accuracy of the iron piece arrangement volume is approximately 1/10, and the homogeneity is increased by repeating. When the number of the nodes is equal to or greater than five, even if an error occurs in the corresponding areas, it is considered that a sufficient accuracy is provided. In the example in FIG. 8, there are about 1500 nodes on one side. In a case that there are two current evaluation planes of the upper and lower shim-tray as shown in FIG. 6, it is considered that the total is about 3000 nodes or more.

In this example, the work process moves to an iron piece arrangement work process step 22S because it is predicted that the shimming can be sufficiently done through confirmation of the iron volume display in FIG. 7 (a) and FIG. 8. The prediction is based on that the attainable homogeneity 17 is sufficiently better than the target value and the arranged iron piece has a possible volume.

When it is determined that the attainable homogeneity or the volume of the iron piece is improper in a step 20S of determining whether the shimming is possible or not, the work process proceeds to a magnetic field adjustment possibility determining step 21S of determining whether target magnetic field adjustment is possible. When it is determined that the magnetic field adjustment is possible in the magnetic field adjustment possibility determining step 21S (“YES”), the work process returns to eigen mode selection and the target magnetic field determining step 17S However, even if various conditions are changed, when it is determined that the magnetic field adjustment is impossible in the magnetic field adjustment possibility determining step 21S of determining whether the magnetic field adjustment to the target is possible or not, the magnet is poor, and the work process advances to a repair and adjustment step 41S.

FIG. 7 (b) shows a spectrum when the shimming is completed. Shimming reaches a homogeneity of 17 ppm. This has not so large difference from the originally predicted value of 15 ppm, so that the prediction of the homogeneity was done at a good accuracy. During reaching the homogeneity of the spectrum in FIG. 7 (a), the repeated work process is done as shown by the flowchart in FIG. 1. The necessity of repeated work process has been described. However, this will be described with an actual example.

The magnetic field adjustment possibility is determined in the step 21S. The content will be described. There may be a case where a sufficient homogeneity cannot be obtained with an appropriate adjustment volume (shimming iron volume) even if the eigen-mode selection is considered again by returning to the step 17S via the step 21S. More specifically, this is because a manufacturing accuracy of the magnet is insufficient, so that the magnetic field is improper, and if it is tried to obtain the target homogeneity, a large volume of the iron piece should be arranged, which is actually impossible. This evaluation provides detection of poorness of the magnetic field without conducting the magnetic field adjustment. When the magnetic field is poor, an appropriate repair is done. From a distribution of the adjustment volume a problematic place can be estimated. In addition, if the repair is impossible, it can be determined that the product is poor. Accordingly, the present invention provides an advantageous effect in that the determination can be provided in which hand is used by repeating the magnetic field adjustment.

When the prediction shows a sufficient attainable homogeneity, an iron piece distribution calculation result necessary for the adjustment is outputted as an enlarged display on a print on paper or by projection, the work process of arranging the iron piece for shimming is carried out in accordance with the distribution. In the iron volume arranged by the shimming work process, there is an error in conversion from the current potential to the iron piece because the volume and a position have errors and a degree of magnetizing of the iron piece depends on a characteristic of material of the iron piece and a distribution of magnetic field within the magnet. Accordingly, one-time work process cannot reach the attainable homogeneity. Therefore, the work process is repeated as shown in FIG. 1 to make the magnetic field closer to a homogeneous state.

### SECOND EMBODIMENT

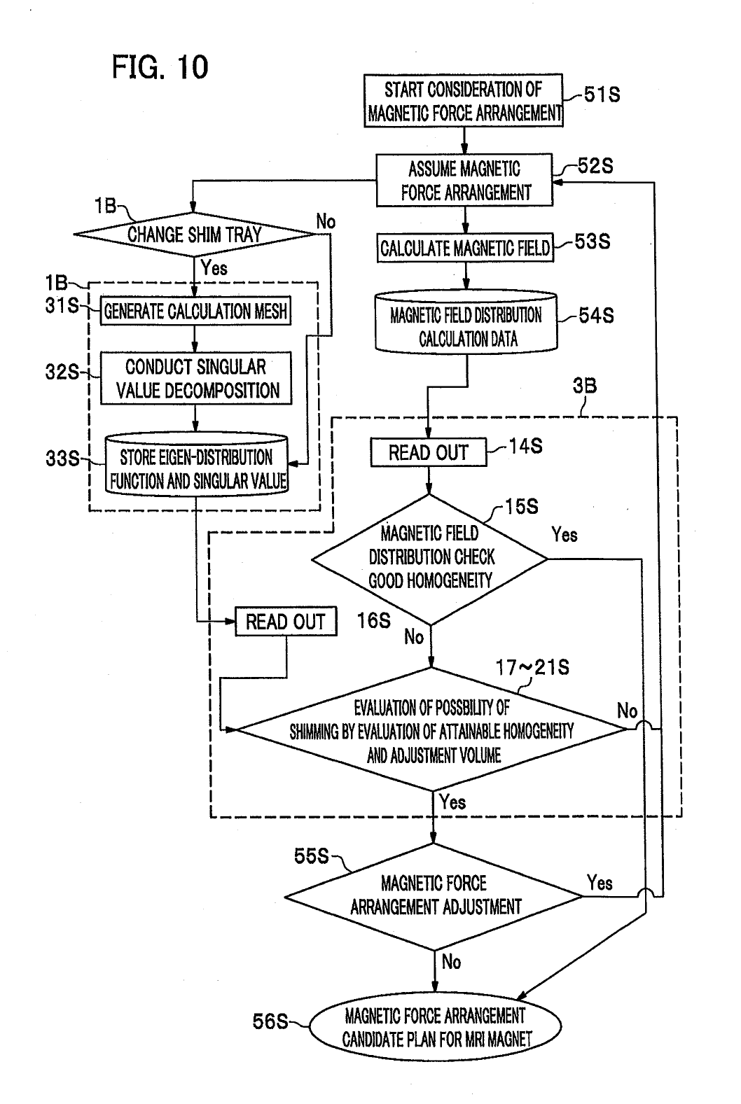

Will be described a second embodiment. It has been described previously that this method is usable for inspection of quality after manufacturing. However, this method is also usable for designing a magnet in accordance with the same determination. A flowchart of this case is shown in FIG. 10. In this embodiment, the magnetic adjustment is done through calculation, this method is applied to a magnetic force arrangement design by confirming that the target magnetic field accuracy can be reached. After a magnet motive force arrangement consideration start step 51S, a magnet motive force arrangement assuming step 52S is done. A magnetic field calculation step 53S is done on the basis of the magnet motive force arrangement. In addition, a singular value decomposition is done on the basis of the arrangement in the shimming tray from the magnet motive force arrangement, and the result is stored. This pre-calculation part 1B is the same as that of the first embodiment. The part 1B is conducted only in a case where it is determined that the shim-tray change is necessary in the magnetic force arrangement improvement determination step 56S on the basis of the magnetic force arrangement assuming step 52S. The pre-calculation part 1B is similar to that in FIG. 1. It is determined whether existing singular value decomposition data can be used in the step 56S. In accordance with the result, only the step 16S reading out the data set of the singular value decomposition result is performed.

The magnetic field data reading step 14S for reading out the magnetic calculation result and a step 15S of determining that the magnetic field homogeneity is good are conducted. When the homogeneity has reached a good value, a magnet motive force arrangement candidate plan for an MRI magnet step 57S is conducted. Generally, it is determined whether the homogeneity becomes good by shimming through the method of the present invention that has been described from the magnetic field distribution. When the homogeneity cannot be sufficiently improved by shimming, or when it is determined that shimming is impossible because the iron volume necessary for shimming is excessive, the work process returns to the magnet motive force arrangement assuming step 52S. This determination part 3B is the same steps of 17 to 21S in FIG. 1. The magnetic field adjustment calculation part 3B is the same as that denoted with 3B in FIG. 1.

When shimming is possible, it is considered whether it can be improved by conducting the magnet motive force arrangement adjustment in the step 56S with reference to the iron volume necessary for shimming and a structural design of the whole of the magnet. When the re-consideration of the magnet motive force arrangement is not done, the magnet motive force arrangement candidate plan 57S is done. In addition, when the magnet motive force arrangement is corrected, the work process returns to a part of the magnet motive force arrangement assuming step 52S. When the magnet motive force arrangement is considered again, it can be considered that this may occur in, for example, a case where a magnetic field on the superconducting coil is too excessive, or a case where the electromagnet force causes a difficulty in a supporting mechanism.

As mentioned above, the shimming according to the present invention is virtually done thorough calculation to obtain a candidate of the magnetic force arrangement. In designing the magnet motive force arrangement, for a magnet motive force arrangement of which homogeneity is determined to be sufficient, an entire design such as a magnetic motive force quantity, an electromagnetic force, and a stress, is conducted to determine whether the magnet is successfully formed. When it is difficult to successfully form the magnet, the design is restarted from the step of assuming the magnet motive force arrangement again.

In FIG. 1, as a magnetic field adjusting means, a method of using the magnetic moment by the magnetized iron piece 4 is described as the iron piece arrangement work process step 22S. However, as described in FIG. 3, the magnetized iron piece is equivalent to a current in the small coil 3 as described in FIG. 3. Then, small coils are arranged in meshes in FIG. 8 and it is possible to adjust the current 1 in accordance with the magnetic moment distribution calculated in the method as a replacement of the iron piece arrangement work process step 22S.

In the method of the present invention, there may be a case where a magnetic field adjustment requiring a negative volume may be required. When the magnetic field adjustment is done by current adjustment by the small coil, it can be done by changing a polarity, and when a permanent magnet is used, it can be done by changing a direction. However, magnetization of the iron piece is determined by a peripheral magnetic field circumstance, and the polarity cannot be changed. The negative quantity in this case is considered as follows:

When the selection was made up to a high-numbered part, a part of negative quantity is not arranged. Arrangement of only positive volume part makes a roughness vibration spatial wavelength of the error magnetic field approximately a half, so that the number of eigen-mode order of the error magnetic components that cannot be cancelled as a result of no arrangement of the negative volume shifts to a high-number side of which the number of order is approximately twice the original. Accordingly, the magnetic field intensity decreases and thus can be neglected in magnetic field adjustment. However, when the magnetic field adjustment is done in which relatively-low-numbered eigen-modes are selected, a demand for the negative volume can be generally adjusted by a method of reducing the volume of the iron pieces that have been already arranged in the adjustment up to the high-numbered magnetic field adjustment. However, occasionally, when the volume of the iron pieces in a mesh has been already zero, the iron pieces are removed from the vicinity thereof. The “vicinity” means that a region of closed contour line. Nevertheless, if there is no iron piece to be removed, a specific eigen-mode is intentionally removed from magnitudes necessary for correction to eliminate negative volume. Selecting the specific eigen-mode from high-numbered modes makes affection on the magnetic field small.

In the embodiments shown in FIG. 1 or 10, making the magnetic field adjustment calculation part 3B as software provides a support tool for magnetic field adjustment with a mobility by use with stored data of singular value decomposition result.

### THIRD EMBODIMENT

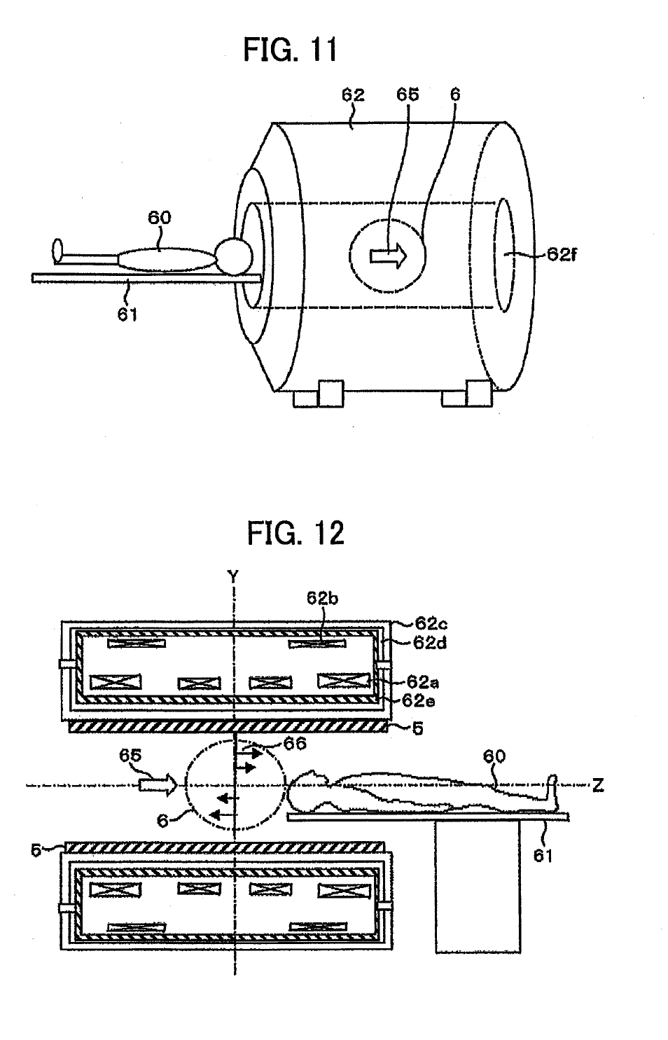

Because the calculation method and the process of the shimming can be performed also in the magnet device 62 for a vertical magnetic field type and the magnet device 62 for a horizontal magnetic field type through the same thinking, they are applicable to the magnetic field adjustment (shimming) for a horizontal magnetic field type MRI, a quality control, and the electric motive force arrangement design. However, because of difference in a shape of the magnet devices 62, there are different points in a calculating procedure and arrangement positions of the iron piece 4. Accordingly, this will be described as a third embodiment blow. In the third embodiment, this will be applied to the magnet device 62 for the horizontal magnetic field type MRI shown in FIG. 11. In this case, in a bore 62f (a hollow sleeve hole) penetrating a center part of the magnet device shown in FIG. 11, a region (the shim-tray 5) usable for shimming in a sleeve shape is arranged. A plane of the shim-tray 5 becomes a sleeve region surrounding a patient to be inspected as shown by the cross section in FIG. 12. It surrounds the shim tray 5 in a sleeve shape and is surrounded by a vacuum vessel 62c in a sleeve shape for heat insulation which has a radiation shield 62d and a cryogenic temperature vessel 62e in which a coil group 62a is arranged. The magnetic device 62 including the above-described members surrounds the shim tray 5. An imaging region 6 is a geometrical center of the magnet and is a region surrounded by a broken line having a center on an intersection of three orthogonal symmetric axes. An image is captured while a gradient magnetic field 19 is generated. The gradient magnetic coil is also disposed in a region similar to the shim tray 5. The shim tray 5 is frequently disposed inside the gradient magnetic field coil assembly.

A cross section of a sleeve of the shim tray 5 is not necessarily a circle cross section. Because the singular value decomposition is utilized, a response matrix from the magnetic member on the shim tray to the magnetic field of the imaging region is applicable to a given calculation system. For example, when the shim tray is arranged between coil groups having a cross section of the gradient magnetic field coil according to Patent Document 3, the sleeve shape has an oval cross section. On the other hand, in this method, the shimming can be performed by the method which has been described.

Meshes of the shim tray 5 of the magnet device for the horizontal magnetic field type of MRI device are different from the meshes for the case of the vertical magnetic field shown in FIG. 6. This is because a plane forming the shim tray 5 having the sleeve shape is parallel to the magnetic field. In FIG. 6, the shim tray plane is a plane vertical to the magnetic field.

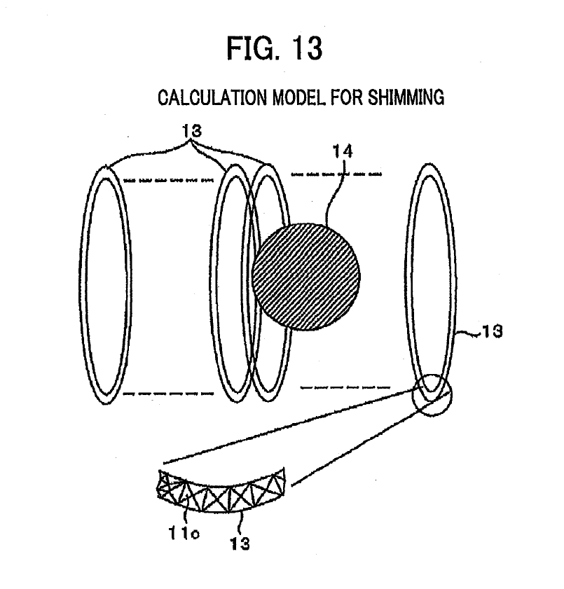

To utilize DUCAS calculation, it is necessary that a magnetizing direction is vertical to the plane, the iron piece is magnetized by influence of the magnetic field around there, and the magnetizing direction is approximately in a static magnetic field magnetic line of force direction 65 of the magnetic field around there. Accordingly, the magnetizing direction of the iron piece 4 is in a direction in a plane of the shim tray. To solve this, a lot of current potential evaluation planes 13 in a ring like shape are arranged in an axial direction (magnetic line of force direction of the magnetic field in the horizontal direction) as shown in FIG. 13. A lot of nodes 11 which are not at ends of the plane (referred to as in-plane nodes) are secured in a circumferential direction. The in-plane node 11 is equivalent in assuming a circular current around the in-plane node, which corresponds to arrangement of a magnetic moment M.

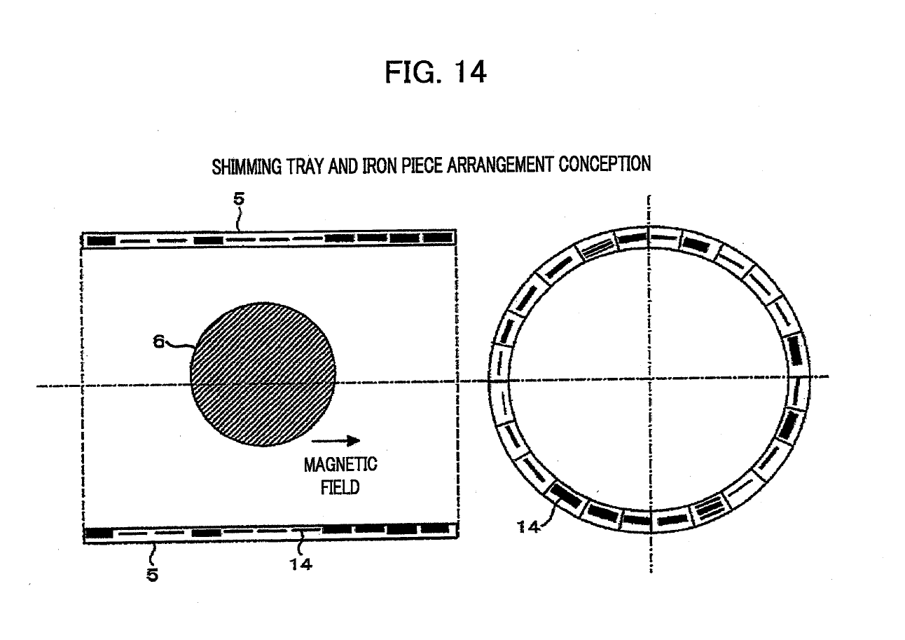

In the embodiment of the horizontal type of magnetic field apparatus, a situation will be described on the shim tray plane. In the vertical magnetic field apparatus, the regions (shim trays 5) which are a pair of flat planes for arranging the iron pieces 4 as shown in FIG. 5 are located at a position of a sleeve shape disposed at a bore 62f of the magnet as shown in FIG. 8, and disposed such that the iron pieces 4 are arranged to be distributed in a circumferential direction and an axial direction. This arrangement is made in accordance with the iron piece volume 10 obtained by the calculation method which is common to the vertical magnetic field type of apparatus (open type of apparatus) which has been described). The iron pieces 4 are arranged to be distributed regarding the axial direction positions (magnetic field direction positions) and positions in circumferential direction of the cross section of the sleeve shape. This situation is shown in FIG. 14 with a thickness of the iron piece being varied.

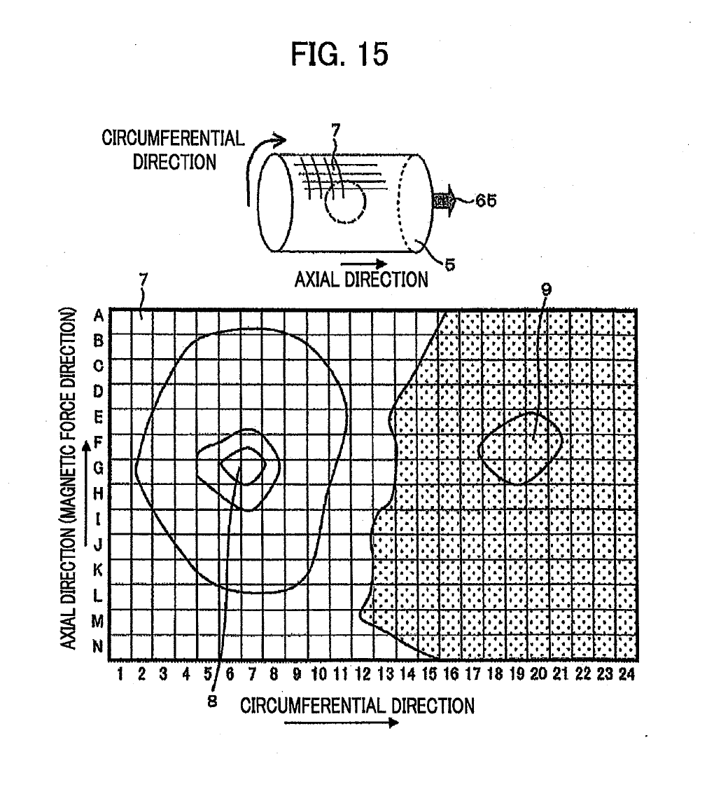

The figure showing the distribution of the iron pieces and current potential distribution for correction shown in FIG. 8 for the magnet device 62 of the vertical magnetic field type of MRI becomes a distribution views indicated with angular coordinates indicating a circumferential direction and angular direction addresses, a positional coordinates indicating a position in the axial direction and addresses, as shown by a lower part of FIG. 15. An upper part of the FIG. 15 describes the shim tray 5. On the shim tray 5, addresses are arranged which are the same as those on the current potential evaluation plane 13, and volumes obtained by the calculation are arranged at the addresses. This is divided into 24 parts in the circumferential direction and into 14 parts A to N in the axial direction (static magnetic field line of force direction 65). To achieve a necessary accuracy (homogeneity) of the magnetic field, an order of correction (the number of eigen modes) is examined, and such a division is required that a distribution of the order can be reproduced. The number is approximately from 15 to 30 both in the circumferential direction and the axial direction. In the meshes 7 shown in the lower view of FIG. 15 a number indicating a volume of the iron piece 4 is actually indicated as shown in FIG. 8. However, here, the numbers indicating volumes of the iron pieces are not indicated.

In the magnet device 62 of the vertical magnetic field type of apparatus for the vertical magnetic field type MRI, the plane where the meshes are arranged and the plane for calculating the current potentials for correction (i.e., the shim tray plane) are present on the same plane. On the other hand, in the horizontal magnetic field type of apparatus, the current potential evaluation plane 13 is different from the sleeve plane of the shim tray 5. Accordingly, indication in FIG. 15 is made such that values of the intermediate nodes 11c in the current potential distribution calculated in the respective current evaluation planes 13 in ring like shape are projected on the sleeve plane regarding a geometric center of the magnet. It should be considered that arranging all the intermediate nodes 11c on the same sleeve like planes is convenient for this indication.

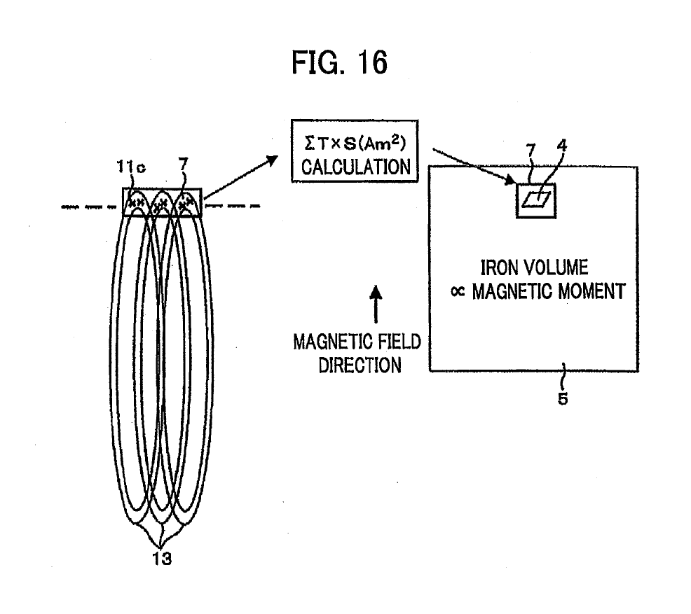

With reference to FIG. 16 will be described a calculation of the iron piece volume 10 indicating arranged volumes of the iron pieces 4. An iron piece arrangement volume is calculated by surface integration of a current potential. However, because the current evaluation plane (current potential evaluation plane 13) is different from the shim tray plane, the iron piece arrangement volume is calculated over some ring shape planes as shown in FIG. 16. Accordingly, it is convenient to arrange many ring shape current planes to arrange one or more ring shape current plane at a region corresponding to the meshes 7.

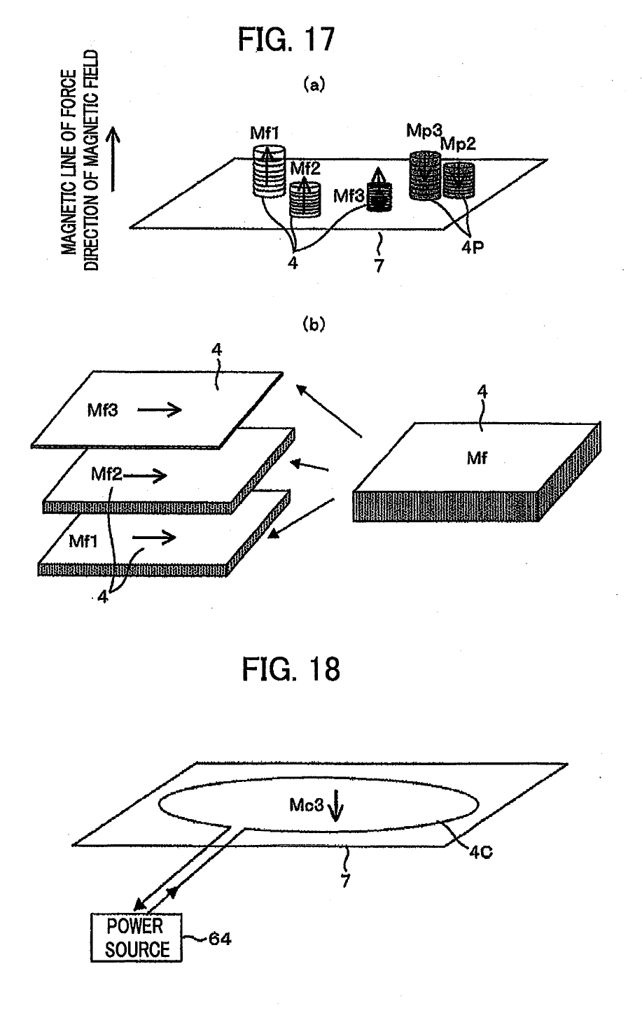

Will be described a status inside a frame of the mesh 7 in the actual shimming. As shown in FIG. 17, insides of the actual meshes in the first and second embodiments are the same and thus it is assumed that some iron pieces 4 having different volume are arranged. FIG. 17 shows two kinds of cases. A method of combining plate shape iron pieces 4 drawn in a lower side is mainly adopted for the magnet device 62 for the horizontal magnetic field. As argued regarding FIG. 14, this iron piece shape regards the shape of the shim tray 5 for the iron piece arrangement.

Magnitudes of the magnetic moments are different as indicated as Mf1 to Mf3. The quantities of the iron piece materials 10 (volumes) are adjusted by combining iron pieces 4 having different volumes so as to generate necessary magnetic moments, as shown in FIGS. 9 and 16:

Mf=ΣTi×Si(Am²) (18)

In this equation, the summing is carried out over some current potential evaluation planes at the positions of the mesh 7. In addition, Ti is a current potential value (A) of the node i within the frame, and Si is an element area on the current potential evaluation plane 13 to which the node belongs. Because the node belongs to a plurality of elements, it is not a problem to consider that ⅓ of the respective triangle elements shown here belong to respective nodes 11. A conversion method between the iron piece volume 10 and the magnetic moment M has been argued in FIG. 3 and is around 170 Acm²/1 cc. The magnetic moments necessary for the meshes 7 are converted into volumes of iron pieces, and necessary volumes are arranged within the meshes. In a case where the iron pieces are not magnetically saturated because a magnetic field is weak, in which case the magnetizing M is different in the conversion coefficient as different from that of the saturation magnetizing, a magnitude is determined with reference to the magnetizing curve of the material (M-H curve, M=magnetizing intensity T, H=an intensity of magnetic field A/m or T). These methods are the same as the magnetic field adjustment for the vertical magnetic field type device (open type).

The status of the mesh 7 schematically described at an upper part of FIG. 17 (FIG. 17(a)) shows an arrangement in a case where the iron pieces 4 and bolts of permanent magnets 4P are used. Also in this case, a target volume is obtained by combining some values corresponding to the magnitudes of the magnetic moments (Mf1 to Mf3, Mp1 to Mp3). The shim tray having the sleeve shape in FIG. 14 actually has a pod having a long structure in parallel to an axis of the magnet, and it is assumed that the iron pieces are arranged therein. Twenty-four pods are arranged in FIG. 14 in a circumferential direction. There is a structure for fixing the iron piece in the pod, and has more than ten locations in a direction in parallel to the axis of the magnet. In FIG. 14, eleven fixing locations are drawn in the axial direction. When the number of the pods in the circumferential direction is caused to be equalized to sections in calculation in FIG. 15, the magnetic moments by Eq. (18) are arranged at the fixing location of the corresponding pod. In addition, when the calculating section is large, the iron pieces are arranged at the fixing locations of a plurality of corresponding pods. When the calculation section is small, arrangement is made additionally at the fixing locations of the corresponding pod.

### FORTH EMBODIMENT

The first and second embodiments have been described with examples in which the iron pieces are arranged with volumes for generating necessary magnetic moments. However, as described previously, there may be a case where the volume of the iron piece that can be removed in the mesh 7 is insufficient or zero, when a negative volume is required as a volume 10 of iron piece to be arranged. When a sufficient homogeneity are not achieved even though the control was made as mentioned above, the permanent magnet 4P or a current loop 4C is used instead of the iron piece. These have no problem when being used for the positive iron volume. However, when the control can be done by magnetization of iron, it is desirable to use the iron piece that can provide shimming at a low cost. This status is shown at the upper part of FIG. 17.

In the current loop shown in FIG. 18, if it is assumed that an area within the loop is S1 on the basis of a principle equation, the magnetic moment Mc is given by:

Mc=current×S1

A current from a power source 10 is adjusted in consideration of a sign so as to make the magnetic moment equal to the necessary magnetic moment.

The method of generating the magnetic moment and materials actually used in shimming are shown in FIG. 17. However, another ferromagnetic material may be possible such as nickel or cobalt in addition to this. In this case, a conversion magnetic moment is obtained by checking the magnetization curve as described regarding the permanent magnet, and the obtained necessary volume is arranged in the meshes.

There may be a case where the magnetization cannot be obtained from the magnetization curve. For example, there may be a case where a ferromagnetic material arranged for shimming distributes a peripheral magnetic field (particularly a ferromagnetic material exists around), the magnetic field may be different from the original magnetic field as a result. In this case, it is desirable to measure a degree of magnetization of the ferromagnetic material. For example, before and after the arrangement of the ferromagnetic material piece of which magnetization is unclear, a peripheral magnetic field is measured and compared with a magnetic field change in a case where the magnetization is known. Alternatively, it is compared with a magnetic field variation calculated. In addition, if the magnetization curves are only the known best cases, a precise non-liner magnetic field calculation is conducted and the calculation results are utilized as magnetization calculation values of the arranged iron pieces 4.

According to the first to fourth embodiments, a surer magnetic field adjustment is provided by repeating measurement, adjusting iron piece arrangement calculation, and arranging with conformation of a quality of the magnet and with automatically correcting an error in which the final attainable homogeneity is predicted. In addition, this is usable for the magnet force arrangement designing in which a high magnetic field accuracy is required.

### INDUSTRIAL APPLICABILITY

The present invention provides a method and an apparatus for adjusting the magnetic field to have a desired magnetic field distribution in the magnet apparatus for generating the magnetic field by arranging the ferromagnetic material such as a coil or iron in nuclear magnetic resonance apparatus (MRI) for medical diagnosis. Particularly, in a nuclear resonance application apparatus such as the MRI, the present invention provides the method and apparatus for homogenization in the measurement region with an extreme high accuracy. Particularly, in the shimming work process in which the error magnetic field is corrected by arrangements of the iron piece, the error magnetic field distribution and the iron piece arrangement distribution are corrected to the homogeneity magnetic field distribution with a combination of respective orthogonal basis.

### EXPLANATION OF REFERENCE NUMERALS

1 current
1B pre-calculation part
2 magnetization current
2B magnetic field measurement part
3 small coil
3B magnetic field adjustment calculation part
4 iron piece
4C current loop
4P permanent magnet
5 shim-tray
6 magnetic field measurement evaluation region (imaging region)
7 mesh
8 peak of contour line
9 valley of contour line
10 iron piece volume
11 node
11S magnetic field adjustment start step
12 finite element
12S magnetic field measurement step
13 current potential evaluation plane
13S measured magnetic field storing step
14 set of magnetic field measurement evaluation points
14S magnetic field data reading step
15 selected eigen-mode
15S homogeneity determination step
16 non-selected eigen-mode
16S singular value decomposition result reading step
17 attainable homogeneity
17S step of eigen-mode selection and target magnetic field determination
18 iron volume arranged in mesh
18S calculation step of eigen-mode intensity, correction current potential, iron volume, correction magnetic field distribution, and attainable homogeneity
19 current potential contour line
19S calculation step of spectrum, attainable homogeneity, and iron piece arrangement value
20S determination step of possibility in shimming
21 current by current potential
21S quality possibility determining step
22 line indicating upper limit of a number of order of eigen-mode selection
22S iron piece arrangement work process step
23 line indicating lower limit of intensity of eigen-mode selection
31S calculation mesh generation step
32S singular value decomposition calculation step
33S singular value decomposition result storing step
40S magnetic field adjustment completion step
41S repair and adjustment step
51S magnet motive force arrangement study start step
52S magnet motive force arrangement assuming step
53S magnetic field calculation step
54S magnetic field calculation result storing step
55S shim-tray change necessity determination step
56S magnetic force arrangement improvement necessity determination step
57S step of magnetic motive force arrangement candidate plan for MRI magnet
60 patient
61 patient bed
62 magnet device
62a coil
62b active magnetic shielding coil
62c vacuum vessel
62d radiation shield
62e cryogenic temperature vessel
62f bore
63 connecting column
64 power source
65 static magnetic field line of magnetic force direction
66 gradient magnetic field vector

1. A magnetic field adjustment method for an MRI device having a magnetic field generating device having an region to which a target magnetic field distribution is set, the method bringing the magnetic field distribution in the region close to the target magnetic field distribution, characterized by:
having, as adjusting means, a magnetic field adjustment mechanism capable of arranging a current loop, a ferromagnetic material that is passively magnetized such as an iron piece, or a permanent magnet not depending on an external magnetic field in a sleeve region including the region; and
a magnetic field adjustment work process that performs a magnetic field measurement at a predetermined number of points, calculates an error magnetic field that is a difference from the target magnetic field, obtains a current potential distribution in a region of the magnetic field adjustment mechanism that can approximately correct the error on a plurality of ring shape planes intersecting the magnetic field direction within the region of the magnetic field adjustment mechanism,
converts the current potential distribution into magnetic moments which are summed in a section including one or more calculation points, and arranges a loop current, or a ferromagnetic material piece that corresponds to the summed magnetic moment.

2. A magnetic field adjustment method for an MRI device having a magnetic field generating device having an region to which a target magnetic field distribution is set, the method bringing the magnetic field distribution in the region close to the target magnetic field distribution, characterized by:
having, as adjusting means, a magnetic field adjustment mechanism capable of arranging a current loop, a ferromagnetic material that is passively magnetized such as an iron piece, or a permanent magnet not depending on an external magnetic field in a sleeve region including the region; and
a magnetic field adjustment work process that performs a magnetic field measurement at a predetermined number of points, calculates an error magnetic field that is a difference from the target magnetic field, obtains magnitudes of magnetic moments at a lot of locations for magnetic moment calculation arranged in a region of the magnetic field adjustment mechanism where the error magnetic field can be approximately corrected, makes addition in a section including one or more magnetic moment calculating points, and arranges a loop current, or a ferromagnetic material piece that corresponds to the magnitude of the magnetic moment.

3. The magnetic field adjustment method for the MRI device as claimed in claim 1, characterized in that
a distribution function is selected from eigen-distribution functions that are basis obtained by singular value decomposition, and
the current potential distribution or the magnetic moment distribution for approximately correcting the error magnetic field with the combination of the distribution functions is calculated.

4. The magnetic field adjustment method for the MRI device as claimed in claim 3, characterized in that
correction magnetic field quantities at a magnetic field measurement point in the region to which the target magnetic field is set on the basis of the approximately corrected current potential, or the magnetic moment is calculated,
a predictive value of a residual error magnetic field is obtained by subtracting the corrected magnetic field quantity from the target magnetic field is obtained,
a eigen-distribution function which makes the predictive value of the residual error magnetic field is within a target range of an allowed residual error magnetic field is selected.

5. The magnetic field adjustment method for the MRI device as claimed in claim 1, characterized in that
the magnetic moment is converted into an iron piece density, or the current potential as a quantity proportional to the magnetic moment is converted into an iron piece volume density, and
the iron piece is arranged in accordance with the converted distribution.

6. The magnetic field adjustment method for the MRI device as claimed in claim 1, characterized in that
selection of eigen-distribution functions for obtaining a current potential distribution or a magnetic moment necessary for correcting the error magnetic field is made on a correlation chart (spectrum chart) with a number (order) numbered in accordance with a magnitude order of singular values and eigen-distribution intensity included in the error magnetic field.

7. The magnetic field adjustment method for the MRI device, as claimed in claim 1, characterized in that
a density distribution display including contour lines is made on a circular sleeve included in the magnetic field adjustment mechanism regarding a quantity corresponding to the current potential, or a quantity of the magnetic moment that are calculation result, and
the iron piece is arranged in accordance with the display by an operator.

8. The magnetic field adjustment method for the MRI device as claimed in claim 7, characterized in that
the contour line as well as the plane included in the magnetic field adjustment mechanism for arranging the iron piece are divided into polygons, and
a magnitude of the magnetic moment, or the volume of the iron piece or a permanent magnet is displayed for each divided region with a surface integration value together with the contour line or without the contour line.

9. The magnetic field adjustment method for the MRI device as claimed in claim 8, characterized in that
a peak or valley part indicated with the contour line is collectively integrated, and
the volume thereof is arranged at one place or dispersed over a plurality of places within the peak or valley part.

10. The magnetic field adjustment method for the MRI device as claimed in claim 1, characterized in that
the calculation and a work process from the magnetic field measurement and the magnitude calculation of the magnetic moment to the arrangement of an iron piece volume or a permanent magnet value are repeatedly made.

11. The magnetic field adjustment method for the MRI device as claimed in claim 10, characterized in that
in the repeated calculation and work process, a magnitude of intensity of each eigen-distribution function which is a base for indicating the magnetic field distribution obtained by singular value decomposition is displayed in addition to the error magnetic filed to grasp a progress of the magnetic field adjustment.

12. (canceled)

13. (canceled)

14. A designing method of magnet magnetomotive force arrangements in a designing a electromagnet including a coil for generating a magnetic field and magneto motive force of a magnetic material, characterized in that:
a target magnetic field distribution is given, a magnetic field distribution is calculated from the magnetomotive force arrangement, a magnetic field calculation value is inputted in place of the magnetic field measurement value in claim 13, acceptability in arrangement of the magnetomotive force source arranged is confirmed, the arrangement of the magnetomotive force source is changed until the magnetic field adjustment is acceptable to obtain magneto motive force source arrangement allowing a magnetic field adjustment when the acceptability is not confirmed.

15. The magnetic field adjustment method for the MRI device as claimed in claim 2, characterized in that
a distribution function is selected from eigen-distribution functions that are basis obtained by singular value decomposition, and
the current potential distribution or the magnetic moment distribution for approximately correcting the error magnetic field with the combination of the distribution functions is calculated.

16. The magnetic field adjustment method for the MRI device as claimed in claim 2, characterized in that
the magnetic moment is converted into an iron piece density, or the current potential as a quantity proportional to the magnetic moment is converted into an iron piece volume density, and
the iron piece is arranged in accordance with the converted distribution.

17. The magnetic field adjustment method for the MRI device as claimed in claim 2, characterized in that
selection of eigen-distribution functions for obtaining a current potential distribution or a magnetic moment necessary for correcting the error magnetic field is made on a correlation chart (spectrum chart) with a number (order) numbered in accordance with a magnitude order of singular values and eigen-distribution intensity included in the error magnetic field.

18. The magnetic field adjustment method for the MRI device, as claimed in claim 2, characterized in that
a density distribution display including contour lines is made on a circular sleeve included in the magnetic field adjustment mechanism regarding a quantity corresponding to the current potential, or a quantity of the magnetic moment that are calculation result, and
the iron piece is arranged in accordance with the display by an operator.

19. The magnetic field adjustment method for the MRI device as claimed in claim 2, characterized in that
the calculation and a work process from the magnetic field measurement and the magnitude calculation of the magnetic moment to the arrangement of an iron piece volume or a permanent magnet value are repeatedly made.
